(19) United States
(12) Patent Application Publication
(10) Pub. No.: US 2022/0231120 A1
(43) Pub. Date: Jul. 21, 2022

(54) TRANSISTOR CELL INCLUDING AN IMPLANTED EXPANSION REGION

(71) Applicant: Robert Bosch GmbH, Stuttgart (DE)

(72) Inventors: Alberto Martinez-Limia, Tuebingen (DE); Stephan Schwaiger, Bodelshausen (DE); Daniel Krebs, Aufhausen (DE); Dick Scholten, Stuttgart (DE); Holger Bartolf, Ofterdingen (DE); Jan-Hendrik Alsmeier, Pfullingen (DE); Wolfgang Feiler, Reutlingen (DE)

(21) Appl. No.: 17/595,778

(22) PCT Filed: May 18, 2020
(86) PCT No.: PCT/EP2020/063772

§ 371 Date: Nov. 24, 2021

(30) Foreign Application Priority Data
May 27, 2019 (DE) 10 2019 207 758.7

(51) Int. Cl. H01L 29/06; H01L 29/16; H01L 29/20; H01L 29/10; H01L 29/78; H01L 21/76; H01L 21/761; H01L 29/66

(52) U.S. Cl. CPC H01L 29/063; H01L 29/0696; H01L 29/1608; H01L 29/2003; H01L 29/1095; H01L 29/66734; H01L 21/7602; H01L 21/7605; H01L 21/761; H01L 29/66068; H01L 29/66522; H01L 29/7813

(57) ABSTRACT

A transistor cell including a semiconductor substrate, which has a front side and a rear side, the front side being situated opposite the rear side. An epitaxial layer is situated on the front side. Channel regions are situated on the epitaxial layer. Source regions are situated on the channel regions. A trench and field shielding regions extending from the front side of the semiconductor substrate into the epitaxial layer, the field shielding regions each being situated laterally spaced apart from the trench and the trench having a shallower depth than the field shielding regions. An implanted expansion region having a particular thickness is situated below the trench.

### FIELD

The present invention relates to a transistor cell including an expansion region, to a transistor including a plurality of transistor cells including such an expansion region and to a method for manufacturing such a transistor.

### BACKGROUND INFORMATION

The gate oxide of an n-trench MOSFET is protected during blocking mode from high field strengths by deep, highly doped p-regions. In this case, the highly doped regions have a greater depth than the trenches.

The disadvantage of this is that the conductivity of the transistor is degraded during forward operation.

German Patent Application No. DE 10 2007 023 885 B4 describes epitaxially produced expansion layers below the trench for improving the conductivity of the transistor during forward operation. The dopant concentration during the production of the epitaxial layers changes for a particular time period, so that an area is formed that has a higher doping concentration.

The disadvantage of this is that the doping concentration exhibits a high fluctuation of approximately 25% as a result of the dependency of the growth temperature of the epitaxial layer. This means that the adjustment of the doping concentration is problematic.

An object of the present invention is to overcome this disadvantage.

### SUMMARY

In accordance with an example embodiment of the present invention, a transistor cell includes a semiconductor substrate, which includes a front side and a rear side, the front side being situated opposite the rear side. An epitaxial layer is situated on the front side. Channel regions are situated on the epitaxial layer. Source regions are situated on the channel regions. A trench and field shielding regions extend from the front side of the semiconductor substrate into the epitaxial layer, the field shielding regions each being situated at a lateral distance to the trench. The trench has a shallower depth than the field shielding regions. According to the present invention, an implanted expansion region having a particular thickness is situated below the trench.

An advantage of this is that the conductivity of the transistor cell is high in the forward operation, a high blocking resistance being simultaneously ensured.

In one refinement of the present invention, the implanted expansion region is situated at a depth of 0.5 μm to 3 μm starting from the front side of the semiconductor substrate.

An advantage of this is that commercial implantation facilities may be used.

In one further embodiment of the present invention, the implanted expansion region is situated laterally to the trench. In other words, the implanted expansion region is situated both laterally to the trench as well as below the trench.

This may have the advantage that the current-carrying, implanted region is situated around the trench in a u-shaped manner. This improves the current distribution effect.

In one further embodiment of the present invention, the implanted expansion region is situated spaced apart from the trench.

In one refinement of the present invention, the implanted expansion region has the same conductor carrier type as the epitaxial layer, a doping concentration of the implanted expansion region being higher than a doping concentration of the epitaxial layer.

An advantage of this is that the conductivity of the transistor cell is increased.

In one further embodiment of the present invention, the doping concentration increases along the thickness of the implanted expansion region starting from a side facing the trench. In other words, the implanted expansion region has a retrograde profile.

An advantage of this is that the fields at the gate oxide are reduced and the JFET effect between the field shielding regions is reduced. This means, the conductivity in the forward case and the field load of the oxide in the blocking case are adapted to each other and optimized.

In one refinement of the present invention, the semiconductor substrate includes silicon carbide or gallium nitride.

The transistor according to the present invention includes a plurality of transistor cells, which include a semiconductor substrate that includes a front side and a rear side, the front side being situated opposite the rear side. An epitaxial layer is situated on the front side. Channel regions are situated on the epitaxial layer. Source regions are situated on the channel regions. A trench and field shielding regions extend from the front side of the semiconductor substrate into the epitaxial layer, the field shielding regions each being situated spaced apart from the trench. The trench has a shallower depth than the field shielding regions. According to the present invention, an implanted expansion region having a particular thickness is situated below the trench.

The advantage of this is that the conductivity of the transistor in the forward operation is high.

In one refinement of the present invention, the transistor is a MOSFET.

A method according to an example embodiment of the present invention for manufacturing a transistor including a plurality of transistor cells includes the production of an epitaxial layer on a front side of a semiconductor substrate, the epitaxial layer including doping agents, and the production of field shielding regions, which extend starting from a front side of the epitaxial layer into the epitaxial layer, the field shielding regions including doping agents. The method includes the production of channel regions, the channel regions being situated on the epitaxial layer and the channel regions including doping agents. The method includes the production of source regions, which are situated on the channel regions, the source regions including doping agents, and the implantation of an expansion region having a particular thickness starting from the front side at a depth of 0.5 μm to 3 μm, the expansion region including doping agents. The method includes the activation of the doping agents. In addition, the method includes the production of a plurality of trenches, which extend starting from the front side of the semiconductor substrate into the epitaxial layer, the trenches having a shallower depth than the field shielding regions, the application of first isolation areas on trench surfaces of the trenches, the production of gate electrodes, the production of second isolation areas, which are situated above the gate electrodes, the production of a first metal layer on the front side of the semiconductor substrate, and the production of a second metal layer on the rear side of the semiconductor substrate, the rear side being situated opposite the front side.

An advantage of this is that the doping concentration of the implanted expansion regions or of the expansion layer is more precisely adjustable than during the application of an epitaxial expansion layer.

Further advantages result from the following description of exemplary embodiments and from the figures.

### BRIEF DESCRIPTION OF THE DRAWINGS

The present invention is explained below with reference to preferred specific embodiments and to the figures.

FIG. 1 shows a transistor cell including an implanted expansion region, in accordance with an example embodiment of the present invention.

FIG. 2 shows a method for manufacturing a transistor including a plurality of transistor cells that include an implanted expansion region, in accordance with an example embodiment of the present invention.

### DETAILED DESCRIPTION OF EXAMPLE EMBODIMENTS

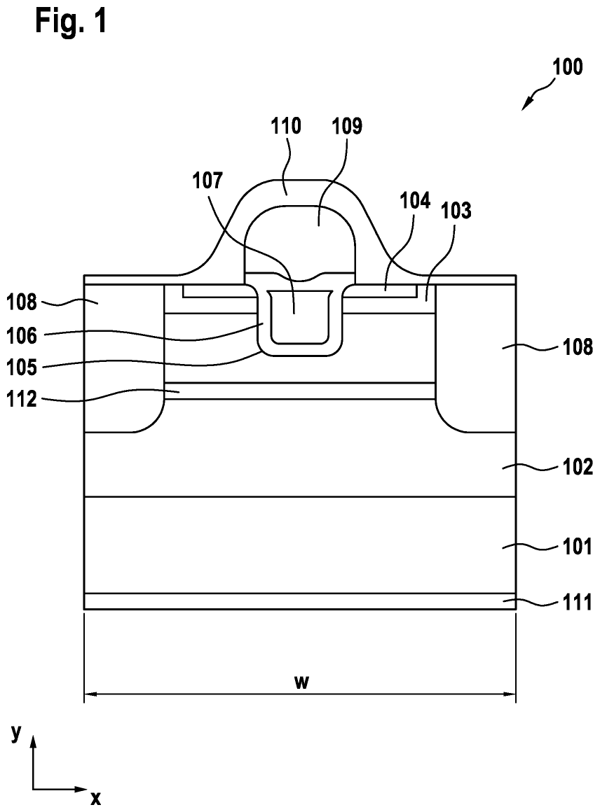

FIG. 1 shows a transistor cell 100 including a semiconductor substrate 101, which has a front side and a rear side, the front side being situated opposite the rear side. Transistor cell 100 has a width w, the so-called pitch. An epitaxial layer 102 is situated on the front side of semiconductor substrate 101. Channel regions 103 or body regions are situated on epitaxial layer 102. Source regions 104 are situated on channel regions 103. A trench 105 and field shielding regions 108 extend from the front side of semiconductor substrate 101 into epitaxial layer 102. Field shielding regions 108 have a greater depth than trench 105. In other words, field shielding regions 108 extend deeper into epitaxial layer 102 than trench 105. Field shielding regions 108 are at a lateral distance to trench 105. This means, field shielding regions 108 are situated at a particular distance laterally to the trench. The particular distance is preferably 0.2 μm to 1.5 μm. An implanted expansion region 112 having a particular thickness is situated below trench 105. The particular thickness is preferably 0.3 μm to 3 μm. Thus, implanted expansion region 112 is situated between field shielding regions 108, field shielding regions 108 covering or overlapping implanted expansion region 112. In other words, implanted expansion region 112 is fully implanted, field shielding regions 108 being doped significantly higher than implanted expansion region 112, so that field shielding regions 108 compensate for implanted expansion region 112. Implanted expansion region 112 is situated starting from the front side of semiconductor substrate 101 at a depth of between 0.5 μm and 3 μm. Implanted expansion region 112 is situated both laterally to trench 105 as well as below trench 105. This means, implanted expansion region 112 is directly adjacent to the side walls of trench 105 and the trench bottom. Alternatively, implanted expansion region 112 are at a particular distance to trench 105 along a main extension direction y. Implanted expansion region 112 includes the same conductor carrier type as the epitaxial layer, the doping concentration of the implanted expansion region being higher than the doping concentration of the epitaxial layer. The doping concentration of implanted expansion region 112 in this case is between 8e15 cm\hat{ }-3 and 1e18 cm\hat{ }-3 and the doping concentration of the epitaxial layer is between 1e15 cm\hat{ }-3 and 1e17 cm\hat{ }-3. A first isolation layer or a first isolation area 106 is situated on a trench surface of trench 105. First isolation area 106 functions as gate oxide. Trench 105 is filled, for example, with polysilicon, the polysilicon functioning as gate electrode 107. A second isolation area 109 is situated above trench 105. A first metal layer 110 is situated on the front side of semiconductor substrate 101. First metal layer 110 functions as front side metallization and represents the source connection. A second metal layer 111 is situated on the rear side of semiconductor substrate 101. Second metal layer 111 functions as rear side metallization and represents the drain connection.

Semiconductor substrate 101, epitaxial layer 102, channel regions 104 as well as implanted expansion region 112 are n-doped. The doping concentration of semiconductor 101 is between 1e18 cm\hat{ }-3 and 1e19 cm\hat{ }-3, the doping concentration of epitaxial layer 102 is between and 1e15 cm\hat{ }-3 and 1e17 cm\hat{ }-3 and the doping concentration of the channel regions is between 1e17 cm\hat{ }-3 and 1e18 cm\hat{ }-3. Source regions 103 and field shielding regions 108 are p-doped. The doping concentration of the source regions is between 1e18 cm\hat{ }-3 and 1e20 cm\hat{ }-3.

Alternatively, semiconductor substrate 101, epitaxial layer 102, channel regions 104 as well as implanted expansion region 112 are p-doped. Source regions 103 and field shielding regions 108 are n-doped.

Semiconductor substrate 101 includes silicon, silicon carbide or gallium nitride.

In one exemplary embodiment, the doping concentration increases within the thickness of implanted expansion region 112 along first main extension direction y starting from a side facing the trench. Implanted expansion region 112 this has a retrograde profile, which has a lower doping concentration in the direction of trench 105 than in the direction of the rear side metallization.

A transistor includes a plurality of transistor cells 100. Transistor cells 100 in this case are strung together along a second main extension direction x, which is situated perpendicularly to first main extension direction y. Such a transistor is, for example, a MOSFET.

The transistor is used in power electronic components, such as in inverters for electric vehicles or hybrid vehicles, in inverters for photovoltaic systems and wind turbines, as well as in traction drives and in high voltage rectifiers.

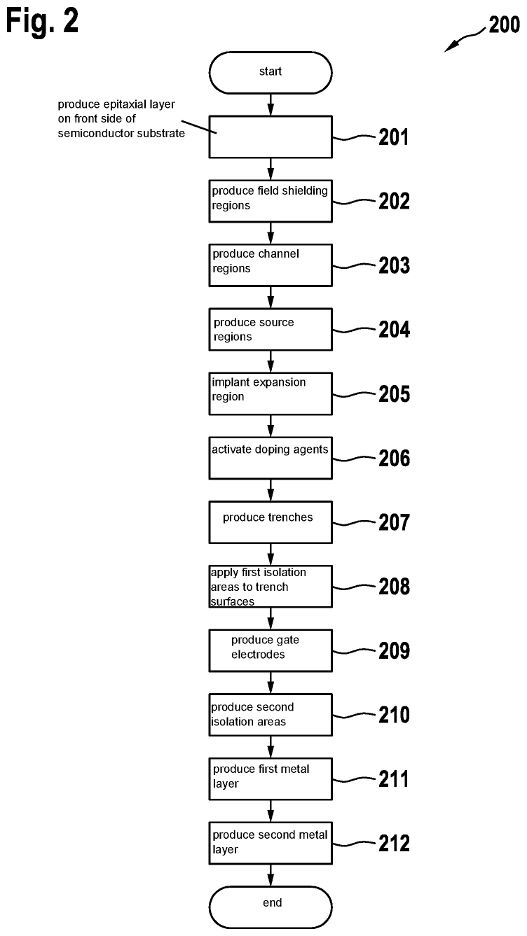

FIG. 2 shows a method 200 for manufacturing a transistor including a plurality of transistor cells. Method 200 starts with a step 201, in which an epitaxial layer is produced on a front side of a semiconductor substrate, the epitaxial layer including doping agents. In a following step 202, field shielding regions are produced, which extend starting from a front side of the epitaxial layer into the epitaxial layer, the field shielding regions including doping agents. In a following step 203, channel regions are produced, which are situated on the epitaxial layer. These are produced by implantation into the epitaxial layer. The channel regions also include doping agents. In a following step 204, source regions are produced, which are situated on the channel regions. The source regions also include doping agents. Steps 201 through 204 are carried out with the aid of masks and implantations. In a step 205 following step 204, an expansion region having a particular thickness is implanted starting from the front side to a depth of 0.5 μm to 3 μm. In the process, high-energy ions of conductor carrier type n are introduced or implanted into the epitaxial layer with an implantation energy of 0.5 eV to 3 eV using multiple implantation energies and implantation doses, so that the expansion region is structured. Thus, the implanted expansion region includes doping agents. The same mask may be used during the implantation, which is used for the structuring of the channel regions. This reduces the manufacturing costs. In a following step 206, the doping agents are activated with the aid of a thermal treatment. In a following step 207, a plurality of trenches is produced with the aid of etching methods. The trenches extend from the front side of the semiconductor substrate into the epitaxial layer, the trenches having a shallower depth than the field shielding regions. In a following step 208, first isolation areas are applied to trench surfaces of the trenches. SiO₂, for example, is deposited in the process. In a following step 209, gate electrodes are produced, by filling the trenches, for example, with a polysilicon. In a following step 210, second isolation areas are produced above the gate electrodes. In a following step 211, a first metal layer is produced on the front side of the semiconductor substrate. In a following step 212, a second metal layer is produced on a rear side of the semiconductor substrate, the rear side being situated opposite the front side.

1-10. (canceled)

11. A transistor cell, comprising:
a semiconductor substrate which has a front side and a rear side, the front side being situated opposite the rear side;
an epitaxial layer situated on the front side;
channel regions situated on the epitaxial layer;
source regions situated on the channel region;
a trench and field shielding regions extending from the front side of the semiconductor substrate into the epitaxial layer, the field shielding regions each being situated laterally spaced apart from the trench and the trench having a shallower depth than the field shielding regions; and
an implanted expansion region having a particular thickness situated below the trench.

12. The transistor cell as recited in claim 11, wherein the implanted expansion region is situated starting from the front side of the semiconductor substrate at a depth of 0.5 μm to 3 μm.

13. The transistor cell as recited in claim 11, wherein the implanted expansion region is situated laterally to the trench.

14. The transistor cell as recited in claim 11, wherein the implanted expansion region is situated spaced apart from the trench.

15. The transistor cell as recited in claim 11, wherein the implanted expansion region includes the same conductor carrier type as the epitaxial layer, a doping concentration of the implanted expansion region being higher than a doping concentration of the epitaxial layer.

16. The transistor cell as recited in claim 11, wherein the doping concentration increases along a thickness of the implanted expansion region starting from a side facing the trench.

17. The transistor cell as recited in claim 11, wherein the semiconductor substrate includes silicon carbide or gallium nitride.

18. A transistor, comprising:
a plurality of transistor cells, each of the transistor cells including:
a semiconductor substrate which has a front side and a rear side, the front side being situated opposite the rear side,
an epitaxial layer situated on the front side,
channel regions situated on the epitaxial layer,
source regions situated on the channel region,
a trench and field shielding regions extending from the front side of the semiconductor substrate into the epitaxial layer, the field shielding regions each being situated laterally spaced apart from the trench and the trench having a shallower depth than the field shielding regions, and
an implanted expansion region having a particular thickness situated below the trench.

19. The transistor as recited in claim 18, wherein the transistor is a MOSFET.

20. A method for manufacturing a transistor including a plurality of transistor cells, the method comprising the following steps:
producing an epitaxial layer on a front side of a semiconductor substrate, the epitaxial layer including doping agents;
producing field shielding regions, which extend starting from a front side of the epitaxial layer into the epitaxial layer, the field shielding regions including doping agents;
producing channel regions, which are situated on the epitaxial layer, the channel regions including doping agents;
producing source regions, which are situated on the channel regions, the source regions including doping agents;
implanting an expansion region having a particular thickness starting from the front side at a depth of 0.5 μm to 3 μm, the expansion region including doping agents;
activating the doping agents;
producing a plurality of trenches, which extend starting from the front side of the semiconductor substrate into the epitaxial layer, the trenches having a shallower depth than the field shielding regions;
applying first isolation areas on trench surfaces of the trenches;
producing gate electrodes;
producing second isolation areas, which are situated above the gate electrodes;
producing a first metal layer on the front side of the semiconductor substrate; and
producing a second metal layer on a rear side of the semiconductor substrate;
the rear side being situated opposite the front side.
